(19) United States
(12) Patent Application Publication
(10) Pub. No.: US 2013/0133940 A1
(43) Pub. Date: May 30, 2013

(54) SYSTEM IN PACKAGE MODULE AND METHOD OF FABRICATING THE SAME

(71) Applicants: Chi-Sheng Chen, Taipei City (TW); Ching-Feng Hsieh, Taipei (TW)

(72) Inventors: Chi-Sheng Chen, Taipei City (TW); Ching-Feng Hsieh, Taipei (TW)

(73) Assignees: ASKEY COMPUTER CORPORATION, Taipei (TW); ASKEY TECHNOLOGY (JIANGSU) LTD., Wujiang (CN)

(21) Appl. No.: 13/344,010

(22) Filed: Jan. 5, 2012

(30) Foreign Application Priority Data
Nov. 25, 2011 (TW) 100143278

(51) Int. Cl. H05K 9/00; H05K 3/10

(52) U.S. Cl. 174/350; 29/846

(57) ABSTRACT

A system in package module and a method of fabricating the system in package module are disclosed. A substrate is provided, including circuit layers, solder pads and dielectric layers. Cutting lines are formed on the substrate. Grounded buried vias are formed in at least one dielectric layer and the circuit layers adjacent to the dielectric layer corresponding to the cutting lines. Electronic elements are disposed on the substrate. An encapsulant is formed on the substrate to encapsulate the electronic elements. The substrate is cut along the cutting lines to expose the grounded buried via. A shielding layer is formed enclosing the encapsulant and sidewalls of the substrate to obtain the system in package module. Therefore, the interference of electromagnetic radiation is diminished and less spaces on the top and bottom of the substrate are occupied.

### FIELD OF THE INVENTION

The present invention relates to package modules, and, more particularly, to a system in package (SiP) module and a method of fabricating the same.

### BACKGROUND OF THE INVENTION

In today's technology industry, Electromagnetic Compatibility (referred to as “EMC”) has been a very important research topic in electromagnetic fields, and how to avoid electromagnetic interference is one of the important issues faced by manufacturers of package modules.

In traditional manufacturing technology for package modules, after a package module is manufactured, a shielding lid is commonly added to the periphery of the package module in order to prevent electromagnetic radiation interference from affecting the package module. However, a package module with a shielding lid requires more space, and the space for circuit patterning is thus reduced.

In addition, in the manufacturing process of system in package (SiP) modules, some manufacturers require molding of the package modules so that the package modules will have the appearance of integrated circuits (IC). However, after molding of the package modules, shielding lids cannot be installed on the package modules and thus electromagnetic radiation interference cannot be prevented.

Therefore, in order to solve the above problems, some manufacturers design a groove corresponding to the package module on the system after the package module is manufactured, wherein the groove corresponds to the location of the package module, thereby preventing the package module from the interference of electromagnetic radiation.

Although the above approach addresses the electromagnetic radiation interference problem with regard to the package modules, the systems need to be designed with additional components, thereby increasing design complexity and manufacturing costs. In addition, the groove corresponds to the location of the package module, so the location of the groove and the location of the package module are constrained by each other, compromising the overall design flexibility.

Moreover, some manufacturers attempt to eliminate the interference of electromagnetic radiation by providing a component on the substrate of the package module, but this takes up too much space on the substrate, and compromises the available space for other electronic elements.

### SUMMARY OF THE INVENTION

In light of the foregoing drawbacks, an objective of the present invention is to provide a system in package module and a method of fabricating the same, which shields the system in package module from interference of the electromagnetic radiation.

Another objective of the present invention is to provide a system in package module and a method of fabricating the same, which occupies less space at the top and bottom of the substrate, releasing more space in which other electronic elements can be placed.

In accordance with the above and other objectives, the present invention thus provides a system in package module, comprising: a substrate including at least one circuit layer, at least one solder pad formed on the circuit layer, and at least one dielectric layer, cutting lines being formed on the substrate, at least one grounded buried via being formed in one of the at least one dielectric layer and the circuit layer adjacent to the dielectric layer corresponding to the cutting lines, the solder pad being in proximity to the grounded buried via; an electronic element and an encapsulant disposed on the substrate, wherein the encapsulant encapsulates the electronic element; and a shielding layer enclosing the encapsulant and sidewalls of the substrate.

Moreover, the present invention provides a method of fabricating a system in package module, comprising the following steps: (1) preparing a substrate including at least one circuit layer, at least one solder pad formed on the circuit layer, and at least one dielectric layer, cutting lines being formed on the substrate, at least one grounded buried via being formed in one of the at least one dielectric layer and the circuit layer adjacent to the dielectric layer corresponding to the cutting lines, the solder pad being in proximity to the grounded buried via; (2) providing at least one electronic element on the substrate; (3) encapsulating the electronic element with an encapsulant on the substrate; (4) cutting the substrate along the cutting lines to expose the grounded buried via; and (5) forming a shielding layer enclosing the encapsulant and sidewalls of the substrate to obtain the system in package module.

Therefore, by forming the shielding layer on the sidewalls of the substrate, electromagnetic radiation is grounded through the shielding layer to eliminate interference of the electromagnetic radiation, thus completely replacing the shielding lid used in the prior art. Also, the system in package module provided by the present invention occupies less space on the top and bottom of the substrate, releasing more space in which other electronic elements can be placed.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional diagram depicting a system in package module according to the present invention;

FIG. 2 is a cross-sectional diagram depicting a circuit layer and a dielectric layer in FIG. 1; and

FIGS. 3 to 8 are schematic diagrams illustrating the steps in a method of fabricating a system in package module according to the present invention.

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

It should be noted that in this application, various elements in the drawings may be exaggerated to facilitate description, and to also assist in reading and identifying elements in the drawing. They are by no means used to limit the present invention.

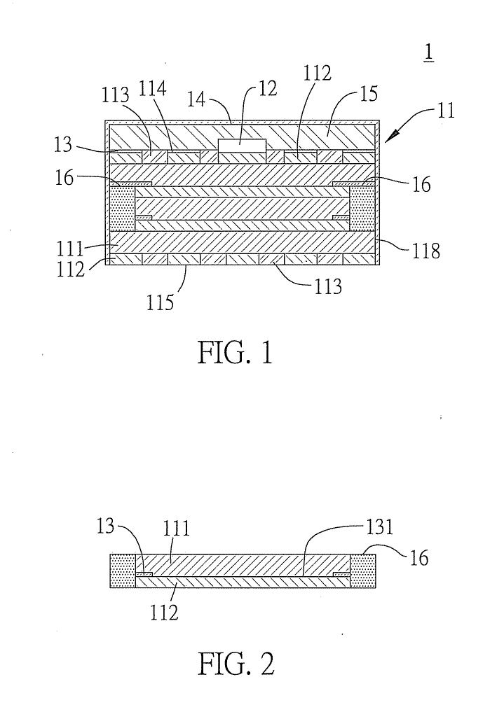

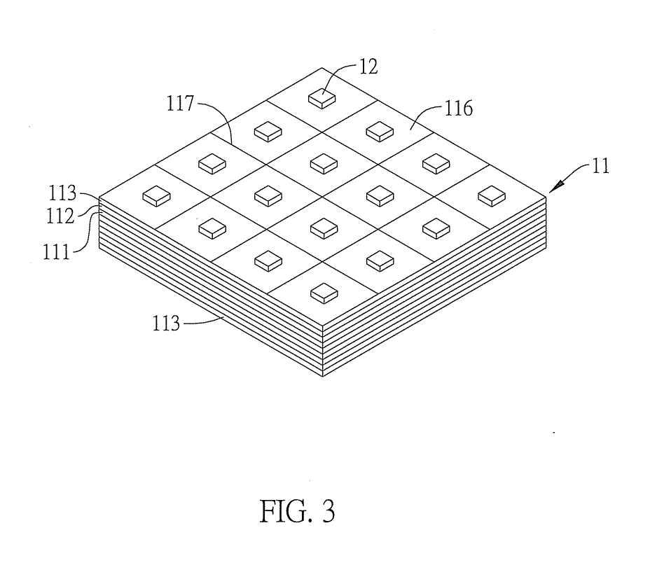

Referring to FIGS. 1 and 2, FIG. 1 is a cross-sectional diagram depicting a system in package (SiP) module 1 according to the present invention, and FIG. 2 is a cross-sectional diagram depicting a circuit layer 112 and a dielectric layer 111 in FIG. 1. The system in package module 1 includes a substrate 11, an electronic element 12, a shielding layer 14, and an encapsulant 15. It should be noted that the system in package module 1 can be used in other types of package modules, and the electronic element 12 described in the present invention is exemplified with a chip, but is not limited thereto. Since the detailed structure of the chip described in the present invention is the same as that of the traditional chips, so it is only schematically shown in the drawing, and the structure of the chip is not further described. In addition, in FIG. 1, although solder pads are typically arranged on the circuit layer 112, but solder pads that are not relevant to the present invention are omitted for simplicity. Furthermore, in FIG. 2, for the same reasons, the complicated layout on the circuit layer 112, which is not the center of the discussion, is omitted for a more concise drawing and to facilitate understanding.

Referring to FIG. 1, the substrate 11 comprises at least one dielectric layer 111 and at least one circuit layer 112 stacked on one another, and insulating layers 113 are formed on the top 114 and bottom 115 of the substrate 11. The circuit layer 112 is used for line layout (that is patterning lines by etching). The dielectric layer 111 is used to prevent adjacent circuit layers 112 from making contact and being short-circuited. The electronic element 12 is disposed on the top 114 of the substrate 11, and makes contact with one of the circuit layers 112. In addition, the insulating layers 113 on the top and bottom of the substrate 11 is provided by coating, and since the circuit layers 112 are etched to form circuits thereon, portions of the insulating layers 113 are formed on the circuit layers 112, and portions of the insulating layers 113 are formed on the surface of the dielectric layers 111 where the circuit layers 112 have been etched away. In an embodiment, the insulating layers 113 are mask layers.

It should be noted that although four circuit layers 112 are shown in FIG. 1, this is for illustration purpose only. In actual practice, an even number of circuit layers 112 is preferable, and more than four layers are especially preferred.

As shown in FIG. 2, at least a solder pad 13 and a dielectric layer 111 are provided on a top surface 131 of the circuit layer 112. The solder pad 13 is disposed on a cutting area reserved in the top surface 131 of the circuit layer 112, wherein the cutting area is located around the periphery of the top surface 131, and grounded buried vias 16 are formed in the dielectric layer 111 and the circuit layers 112 adjacent to the dielectric layer 111. Each solder pad 13 is in proximity with a corresponding grounded buried via 16, wherein the surface area of a region enclosed by the solder pad 13 is slightly larger than the surface area of a region enclosed by the grounded buried via 16. In addition, in an example, the grounded buried via 16 is electroplated with a metal conductor, and the metal conductor is in contact with the solder pad 13.

Referring back to FIG. 1, the grounded buried vias 16 are not formed in all dielectric layers 111. As shown, the grounded buried vias 16 are not formed in the topmost and bottommost dielectric layers, but only in the dielectric layer and adjacent circuit layers between the topmost and bottommost dielectric layers.

Moreover, the encapsulant 15 is formed on the substrate 11 and encapsulates all the side faces and the top face of the electronic element 12. The shielding layer 14 further encapsulates the encapsulant 15 and the sidewalls 118 of the substrate 11. The shielding layer 14 is a metal layer sputtered or plated to cover all the side faces and the top face of the encapsulant 15 and the sidewalls 118 of the substrate 11 to prevent electromagnetic radiation interference generated by external electronic elements (i.e. increase electromagnetic susceptibility), meanwhile preventing the electronic element 12 from generating electromagnetic interference unfavorable to other systems during operation of any supposed functions. It should be noted that any material with metal characteristics, such as silver or copper, can be used as the shielding layer 14 for encapsulating the encapsulant 15 and the sidewalls 118 of the substrate 11, but it is not limited thereto.

It is known from the above descriptions that at least one solder pad 13 is disposed on the top surface 131 of each of the circuit layers 112, and the solder pad 13 on the top surface 131 of each of the circuit layers 112 aligns with each other, and is disposed in proximity of a corresponding grounded buried via 16. The grounded buried vias 16 is formed only in the dielectric layer and the adjacent circuit layers between the topmost and the bottommost dielectric layers.

Refer to FIGS. 1 to 8. FIGS. 3 to 8 are schematic diagrams illustrating the steps in a method of fabricating the system in package module according to the present invention.

As shown in FIG. 3, in step S1, during the process of preparing of a substrate, at least one dielectric layer 111 and at least one circuit layer 112 are stacked on top of the other, and at the top and bottom thereof, an insulating layer 113, a circuit layer 112 and a dielectric layer 111 without any grounded buried via 16 are sequentially formed to form a substrate 11. Each circuit layer 112 has at least one solder pad 13, and the top face of the substrate 11 includes a plurality of mounting areas 116 and cutting lines 117 are formed between two adjacent mounting areas 116. Then, proceed to step S2. In addition, in an example, the insulating layers 113 are mask layers.

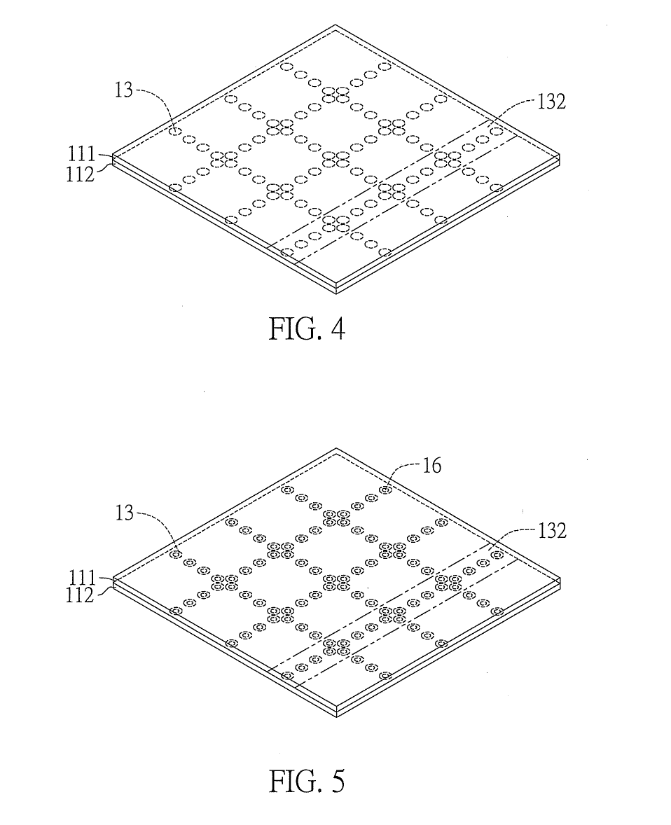

In more details, further discussions of the process for preparing the substrate are given below with reference to FIGS. 4 and 5.

First, as shown in FIG. 4, at least one solder pad 13 is disposed on the top surface of a circuit layer 112. Cutting areas 132 are reserved in the process of manufacturing the circuit layer 112, and the at least one solder pad 13 is formed in the cutting areas 132 reserved in the circuit layer 112.

Then, as shown in FIG. 5, grounded buried vias 16 are formed in the regions enclosed by the solder pads 13 in the cutting areas 132 of the circuit layer 112 and corresponding to the cutting lines 117. The grounded buried via 16 penetrates through the middle dielectric layer 111 and the circuit layers 112 adjacent to the middle dielectric layer 111. The penetration can be performed by mechanical drilling, laser melting or other methods to form the grounded buried via 16, and the solder pad 13 is in proximity to the grounded buried via 16. It should be noted that since the solder pads 13 are located on the top surface of the circuit layer 112, and the grounded buried vias 16 are located in the dielectric layer 111, so the solder pads 13 and the grounded buried vias 16 are shown by broken lines in FIGS. 4 and 5. In addition, in an example, the grounded buried vias 16 are electroplated with metal conductors which are in contact with the solder pads 13.

It should also be noted that the manufacturing process for each circuit layer 112 is the same, so in this application, only one circuit layer 112 is used for descriptions. The locations of the cutting areas 132 reserved in each circuit layer 112 is also the same, so the solder pads 13 disposed on each circuit layer 112 will be aligned with each other. Moreover, the cutting lines 117 on the top face of the substrate 11 also correspond to the cutting areas 132 of each circuit layer 112, so the solder pads disposed in the cutting areas 132 will also correspond to the cutting lines 117.

Furthermore, it should also be noted that, in practice, the cutting areas 132 reserved on the circuit layers 112 are not shown by any particular indications. In FIG. 3, a cutting area 132 is specially drawn to identify the area and to facilitate understanding of the discussions.

As shown in FIG. 3, in step S2, at least one electronic element 12 is provided on the substrate. Then, proceed to step S3.

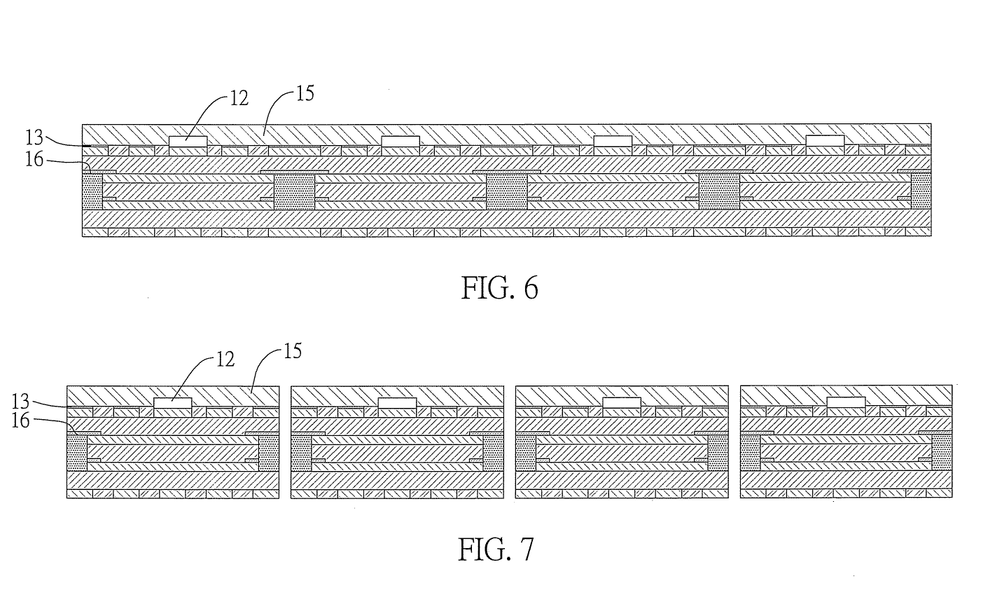

Referring to FIG. 6, in step S3, an encapsulation process is carried out, that is, after the formation of the substrate 11, molding is carried out on each of the plurality of electronic element 12 disposed on the substrate 11, wherein the encapsulant 15 formed during molding covers all the side faces and the top face of the electronic element 12. Then, proceed to step S4.

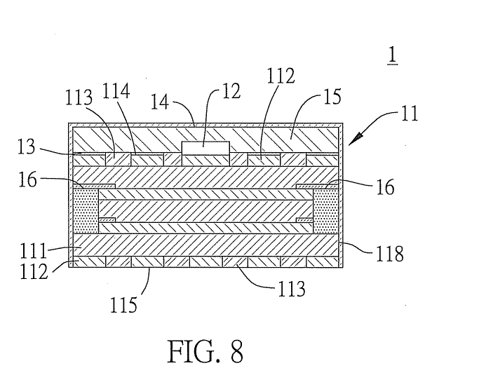

Referring to FIG. 7, in step S4, singulation is performed. That is, after encapsulation is done, the substrate 11 is cut along the cutting lines 117 into a plurality of substrates. Each substrate will have its own electronic element 12 and encapsulant 15, as well as exposed grounded buried vias 16. The locations of the cutting lines 117 correspond to the cutting areas 132 reserved in each circuit layer 112, so the cutting lines 117 are aligned with the cutting areas 132 of each circuit layer 112. Then, proceed to step S5.

Referring to FIG. 8, in step S5, after singulation is completed, a shielding layer 14 is formed on the encapsulant 15 and the sidewalls 118 of the substrate 11 to obtain a system in package module.

It should be noted that the shielding layer 14 is a metal layer that is sputtered or plated onto the encapsulant 15 and the sidewalls 118 of the substrate 11. Owing to the metal characteristics of the shielding layer 14, the system in package module will have good electromagnetic compatibility.

In summary, the system in package module provided in the present invention not only shields the electronic element from the interference of the electromagnetic radiation, but also occupies less space on the top and bottom of the substrate, freeing up more space in which other electronic elements can be placed.

The above embodiments are only used to illustrate the principles of the present invention, and they should not be construed as to limit the present invention in any way. The above embodiments can be modified by those with ordinary skill in the art without departing from the scope of the present invention as defined in the following appended claims.

What is claimed is:

1. A system in package module, comprising:
a substrate including at least one circuit layer, at least one solder pad disposed on the circuit layer, and at least one dielectric layer, cutting lines being formed on the substrate, at least one grounded buried via being formed in one of the at least one dielectric layer and the circuit layer adjacent to the dielectric layer corresponding to the cutting lines, the solder pad being in proximity to the grounded buried via;
an electronic element disposed on the substrate;
an encapsulant formed on the substrate and encapsulating the electronic element; and
a shielding layer enclosing the encapsulant and sidewalls of the substrate.

2. The system in package module of claim 1, wherein the solder pad encloses a region that has a surface area greater than another surface area of another region enclosed by the grounded buried via.

3. The system in package module of claim 1, wherein the grounded buried vias is electroplated with a metal conductor.

4. The system in package module of claim 1, wherein the shielding layer is a metal layer.

5. The system in package module of claim 1, wherein the shielding layer is sputtered or plated onto the encapsulant and the sidewalls of the substrate.

6. The system in package module of claim 1, wherein the substrate includes at least one insulating layer, at least one circuit layer, and at least one dielectric layer without the grounded buried vias, the circuit layer being formed on the dielectric layer, and the insulating layer being formed on a top face and a bottom face of the substrate.

7. A method of fabricating a system in package module, comprising the following steps:
(1) preparing a substrate including at least one circuit layer, at least one solder pad formed on the circuit layer, and at least one dielectric layer, cutting lines being formed on the substrate, at least one grounded buried via being formed in one of the at least one dielectric layer and the circuit layer adjacent to the dielectric layer corresponding to the cutting lines, the solder pad being in proximity to the grounded buried via;
(2) providing at least one electronic element on the substrate;
(3) encapsulating the electronic element with an encapsulant on the substrate;
(4) cutting the substrate along the cutting lines to expose the grounded buried via; and
(5) forming a shielding layer enclosing the encapsulant and sidewalls of the substrate to obtain the system in package module.

8. The method of claim 7, wherein, in step (1), the grounded buried via is formed by mechanical drilling or laser melting.

9. The method of claim 7, wherein, in step (5), the shielding layer is sputtered or plated onto the encapsulant and the sidewalls of the substrate.

10. The method of claim 7, wherein, in step (1), the grounded buried vias is further electroplated with a metal conductor.

11. The method of claim 7, wherein the substrate is formed with at least one insulating layer that is formed on a top face and a bottom face of the substrate.
